(19) United States
(12) Patent Application Publication
(10) Pub. No.: US 2020/0099365 A1
(43) Pub. Date: Mar. 26, 2020

(54) ELECTRONIC PACKAGES COMPRISING STACKED BULK ACOUSTIC WAVE (BAW) RESONATOR and BAW RESONATOR FILTERS

(71) Applicant: Avago Technologies International Sales Pte. Limite, Singapore (SG)

(72) Inventors: John Choy, Westminster, CO (US); Chris Feng, Fort Collins, CO (US)

(21) Appl. No.: 16/139,296

(22) Filed: Sep. 24, 2018

(51) Int. Cl. H03H 9/58; H03H 9/70; H03H 9/02

(52) U.S. Cl. CPC H03H 9/583; H03H 2009/02173; H03H 9/02543; H03H 9/706

(57) ABSTRACT

An electronic package includes a first substrate and a second substrate disposed beneath the first substrate. The electronic package also includes a perimeter wall extending between an inner surface of the first substrate and an opposing inner surface of the second substrate to provide separation between the first substrate and the second substrate. A cavity exists between opposing inner surfaces of the first substrate and the second substrate. A first filter comprising a first plurality of bulk acoustic wave (BAW) resonators disposed over the inner surface first substrate. The electronic package also includes a second filter comprising a second plurality of BAW resonators disposed over the second substrate

### BACKGROUND

In many electronic applications, electrical resonators are used. For example, in many wireless communications devices, radio frequency (rf) and microwave frequency resonators are used as filters to improve reception and transmission of signals. Filters typically include inductors and capacitors, and more recently resonators.

As will be appreciated, it is desirable to reduce the size of components of electronic devices. Many known filter technologies present a barrier to overall system miniaturization. With the need to reduce component size, a class of resonators based on the piezoelectric effect has emerged. In piezoelectric-based resonators, acoustic resonant modes are generated in the piezoelectric material. These acoustic waves are converted into electrical waves for use in electrical applications.

One type of piezoelectric resonator is a bulk acoustic wave (BAW) resonator. Typically, there are two types of BAW resonators: a Film Bulk Acoustic Resonator (FBAR) and a solidly mounted bulk acoustic resonator (SMR). Both the FBAR and the SMR comprise acoustic stacks that are disposed over a reflective element. The reflective element of an FBAR is a cavity, normally in a substrate over which the acoustic stack is mounted. The reflective element of an SMR is a Bragg reflector comprising alternating layers of high acoustic impedance and low acoustic impedance layers.

The BAW resonator has the advantage of small size and lends itself to Integrated Circuit (IC) manufacturing tools and techniques. The FBAR includes an acoustic stack comprising, inter alia, a layer of piezoelectric material disposed between two electrodes. Acoustic waves achieve resonance across the acoustic stack, with the resonant frequency of the waves being determinedby the materials in the acoustic stack.

As devices (e.g., smart phones) introduce ever-increasing functionality, miniaturization of each component becomes necessary and critical. Applying flowing integration processes, the area allocated to various components, such as filters, can be significantly reduced. As will be appreciated, the reduction in allocated areal dimension on a die for filters comprising BAW resonators, can be problematic, particularly in view of the increasing complexity of the filters.

What is needed, therefore, is a structure that overcomes at least the shortcomings of known structures described above.

### BRIEF DESCRIPTION OF THE DRAWINGS

The illustrative embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1A is a cross-sectional view of an electronic package in accordance with a representative embodiment.

FIGS. 1B-1D are a cross-sectional view of a fabrication sequence of the electronic package of FIG. 1A, in accordance with a representative embodiment.

FIG. 2A is a cross-sectional view of an electronic package in accordance with a representative embodiment.

FIGS. 2B-2D are a cross-sectional view of a fabrication sequence of the electronic package of FIG. 2A, in accordance with a representative embodiment.

FIG. 3A is a cross-sectional view of an electronic package in accordance with a representative embodiment.

FIGS. 3B-3D are a cross-sectional view of a fabrication sequence of the electronic package of FIG. 3A, in accordance with a representative embodiment.

FIG. 4A is a top view depicting the layout of a BAW resonator filter disposed over a substrate, in accordance with a representative embodiment.

FIG. 4B is a simplified schematic diagram of a filter arrangement for a duplexer in accordance with a representative embodiment.

FIG. 5 is a cross-sectional view of an electronic package in accordance with a representative embodiment.

FIG. 6 is a cross-sectional view of an electronic package in accordance with a representative embodiment.

### DETAILED DESCRIPTION

In the following detailed description, for purposes of explanation and not limitation, specific details are set forth in order to provide a thorough understanding of illustrative embodiments according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted so as to not obscure the description of the illustrative embodiments. Such methods and apparatuses are clearly within the scope of the present teachings.

In the following detailed description, for purposes of explanation and not limitation, representative embodiments disclosing specific details are set forth in order to provide a thorough understanding of the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted so as to not obscure the description of the representative embodiments. Such methods and apparatuses are clearly within the scope of the present teachings.

It is to be understood that the terminology used herein is for purposes of describing particular embodiments only, and is not intended to be limiting. Any defined terms are in addition to the technical and scientific meanings of the defined terms as commonly understood and accepted in the technical field of the present teachings.

As used in the specification and appended claims, the terms ‘a’, ‘an’ and ‘the’ include both singular and plural referents, unless the context clearly dictates otherwise. Thus, for example, ‘a device’ includes one device and plural devices.

As used in the specification and appended claims, and in addition to their ordinary meanings, the terms ‘substantial’ or ‘substantially’ mean to with acceptable limits or degree. For example, ‘substantially cancelled’ means that one skilled in the art would consider the cancellation to be acceptable.

As used in the specification and the appended claims and in addition to its ordinary meaning, the term ‘approximately’ means to within an acceptable limit or amount to one having ordinary skill in the art. For example, ‘approximately the same’ means that one of ordinary skill in the art would consider the items being compared to be the same.

Relative terms, such as “above,” “below,” “top,” “bottom,” “upper” and “lower” may be used to describe the various elements' relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be “below” that element. Similarly, if the device were rotated by 90° with respect to the view in the drawings, an element described “above” or “below” another element would now be “adjacent” to the other element; where “adjacent” means either abutting the other element, or having one or more layers, materials, structures, etc., between the elements.

The present teachings relate generally to electronic packages comprising BAW resonator filters and BAW resonators. As will become clearer as the present description continues, BAW resonators contemplated include film bulk acoustic wave resonators (FBARs) and surface mount resonators (SMRs). Moreover, BAW resonators of the present teachings may also comprise stacked bulk acoustic resonator (SBAR) device, a double bulk acoustic resonator (DBAR) device, or a coupled resonator filter (CRF) device.

Contemplated applications of the BAW resonators of the present teachings include, but are not limited to communication filter applications and MEMs applications. For example, the bulk acoustic wave (BAW) resonators of the present teachings may be arranged in a ladder-filter arrangement, such as described in U.S. Pat. No. 5,910,756 to Ella, and U.S. Pat. No. 6,262,637 to Bradley, et al., the disclosures of which are specifically incorporated herein by reference. The electrical filters may be used in a number of applications, such as in duplexers and multiplexers.

Certain details of BAW resonators, including materials and methods of fabrication, may be found in one or more of the following commonly owned U.S. patents and patent Applications: A variety of devices, structures thereof, materials and methods of fabrication are contemplated for the first and second acoustic resonators 118, 120 of the electronic package 100. Various details of such FBAR and SMR devices contemplated for use as the first and second acoustic resonators 118, 120 of the electronic package 100, and corresponding methods of fabrication may be found, for example, in one or more of the following U.S. patent documents: U.S. Pat. No. 6,107,721, to Lakin; U.S. Pat. Nos. 5,587,620, 5,873,153, 6,507,983, 7,388,454, 7,629,865, 7,714,684, 8,436,516, 9,479,139, 9,444,428, 6,060,818, 6,060,818C1 (Ex Parte Reexamination Certificate) and U S Patent Application Publication Nos. 20130015747, 20170155373, 20170085247 and 20150145610 to Ruby et al.; U.S. Pat. Nos. 7,369,013, 7,791,434, 8,188,810, and 8,230,562 to Fazzio, et al.; U.S. Pat. Nos. 7,280,007, 9,455,681 and 9,520,855 and U.S. Patent Application Publication No. 20140174908 to Feng et al.; U.S. Pat. Nos. 8,248,185 and 8,902,023 and U.S. Patent Application Publication No. 20120326807 to Choy, et al.; U.S. Pat. Nos. 7,345,410, 9,136,819 and 9,602,073 and U.S. Patent Application Publication Nos. 20170288628, 20150326200 and 20150240349 to Grannen, et al.; U.S. Pat. Nos. 6,828,713 and 9,088,265 and U.S. Patent Application Publication Nos. 20160352306 and 20150381144 to Bradley, et al.; U.S. Pat. Nos. 7,561,009, 7,358,831, 9,243,316, 8,673,121 and 9,679,765 and U.S. Patent Application Publication No. 20140246305 to Larson, III et al.; U.S. Pat. Nos. 9,197,185, 9,450,167, 9,590,165, 9,401,691 and 9,590,165 and U.S. Patent Application Publication Nos. 20170288636, 20170288122 and 20160126930 to Zou, et al.; U.S. Pat. No. 8,981,876 to Jamneala et al.; U.S. Pat. Nos. 9,484,882, 9,571,063, 9,621,126, 9,691,963, 9,698,754, 9,608,594, 9,634,642, 9,548,438, 9,698,753, 9,577,603, 9,525,397, 9,748,918, 9,484,882, 9,571,064 and 9,490,418 and U.S. Patent Application Publication Nos. 20170288121, 20170214387, 20170047907, 20160308509, 20160079958 and 20150280687 to Burak, et al.; U.S. Pat. Nos. 9,768,353 and 9,564,553 to Katona, et al.; U.S. Patent Application Publication Nos. 20160352308 and 20160191015 to Ivira, et al.; U.S. Pat. No. 9,680,445 to Barfknecht, et al.; U.S. Patent Application Publication No. 20150349745 to Small; U.S. Patent Application Publication No. 20150311046 to Yeh, et al.; U.S. Patent Application Publication No. 20150280688 to Ortiz, et al.; U.S. Pat. No. 9,680,439 and U.S. Patent Application Publication No. 20150247232 to Nikkel, et al.; U.S. Pat. No. 9,667,220 to Sridaran, et al.; U.S. Pat. No. 9,608,582 to Bi, et al.; and U.S. patent application Ser. No. 15/661,468 to Ruby, et al., and filed on Jun. 27, 2017. The entire disclosure of each of the patents, patent application publications, and patent application listed above are hereby specifically incorporated by reference herein. It is emphasized that the components, materials and methods of fabrication described in these patents and patent applications are representative, and other methods of fabrication and materials within the purview of one of ordinary skill in the art are also contemplated.

Examples of stacked bulk acoustic resonators, as well as their materials and methods of fabrication, may be found in U.S. Pat. No. 7,889,024 to Paul Bradley et al., U.S. Patent Application Publication No. 2012/0248941 to Shirakawa et al., and U.S. Patent Application Publications Nos. 2012/0218056, 2012/0280767, and 2012/0293278 to Burak et al. U.S. patent application Ser. No. 13/658,024 to Nikkel et al.; U.S. patent application Ser. No. 13/663,449 to Burak et al.; U.S. patent application Ser. No. 13/660,941 to Burak et al.; U.S. patent application Ser. No. 13/654,718 to Burak et al.; U.S. Patent App. Pub. No. 2008/0258842 to Ruby et al.; and U.S. Pat. No. 6,548,943 to Kaitila et al. Certain details of temperature compensation in the context of acoustic resonators are described in U.S. Pat. No. 7,345,410 to Grannen et al. and U.S. Pat. No. 7,408,428 filed Oct. 29, 2004 to Larson et al. The respective disclosures of the above patents and patent applications are specifically incorporated herein by reference. It is emphasized that the components, materials and method of fabrication described in these patents and patent applications are representative and other methods of fabrication and materials within the purview of one of ordinary skill in the art are contemplated.

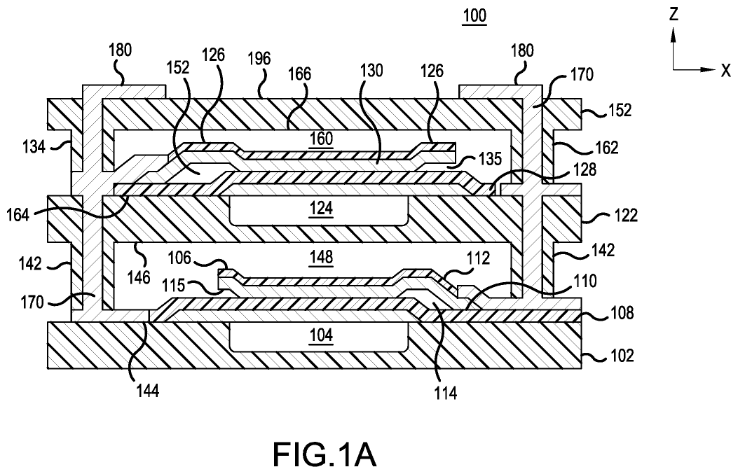

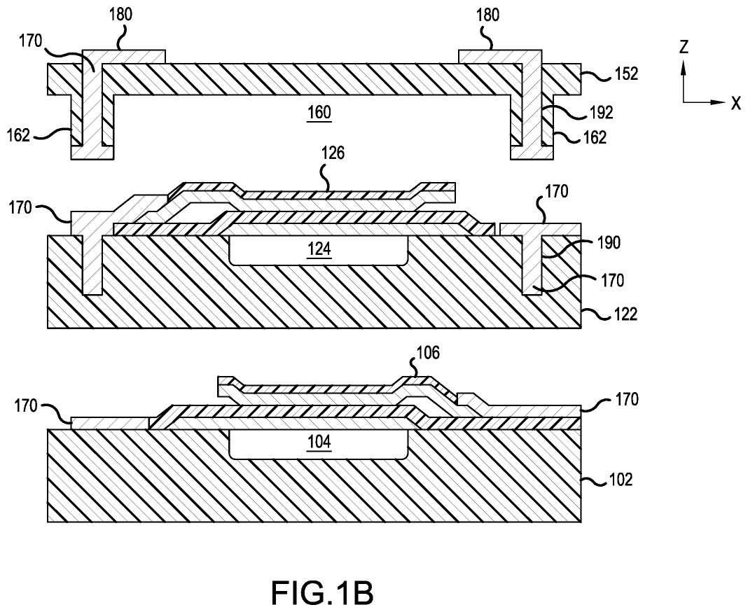

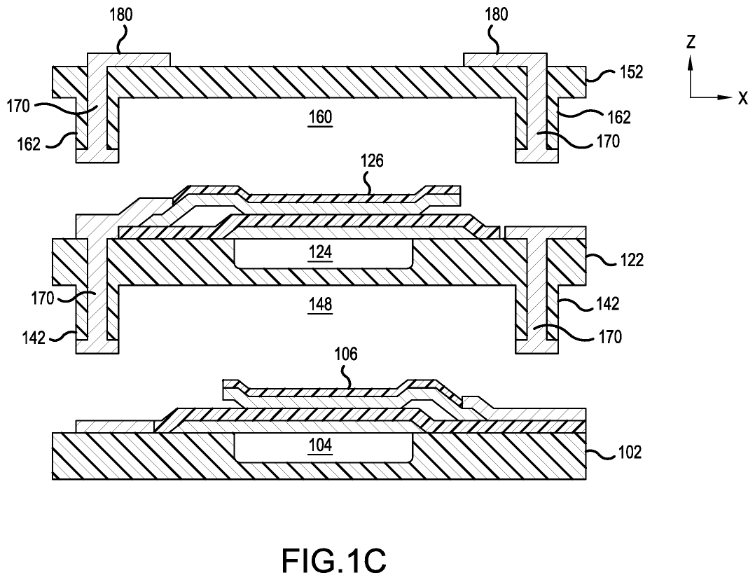

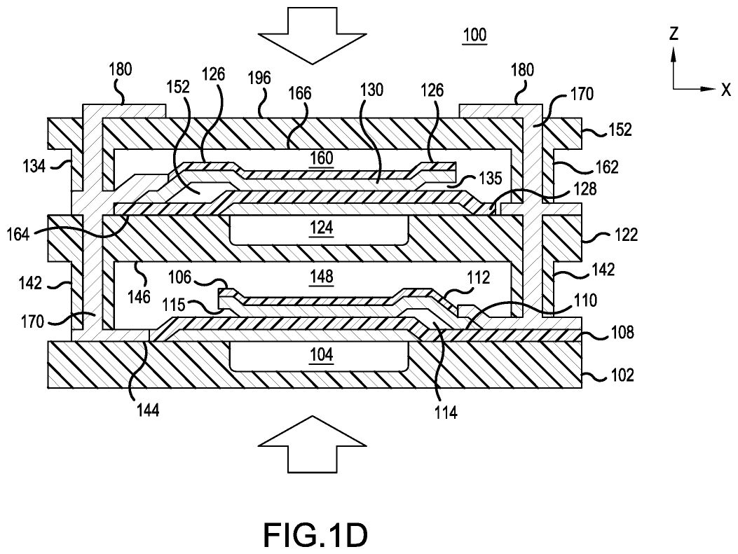

FIG. 1A is a cross-sectional view of an electronic package 100 in accordance with a representative embodiment. The electronic package comprises a first substrate 102, with a first acoustic reflector 104 disposed therein. In certain embodiments (FBAR), the first acoustic reflector 104 is a cavity, and in other embodiments (SMR), the acoustic reflector is a distributed Bragg reflector comprising layers of alternating high acoustic impedance and low acoustic impedance materials.

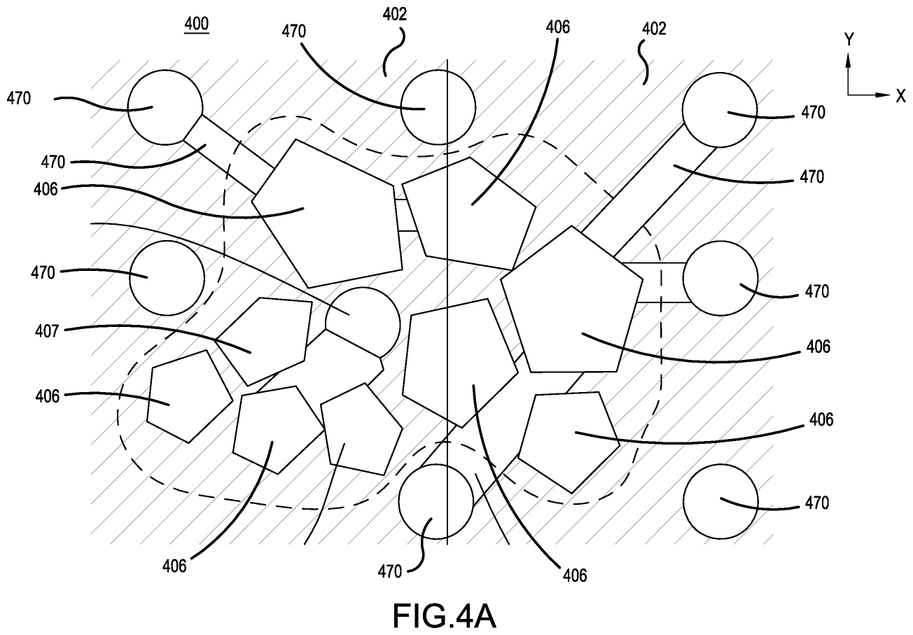

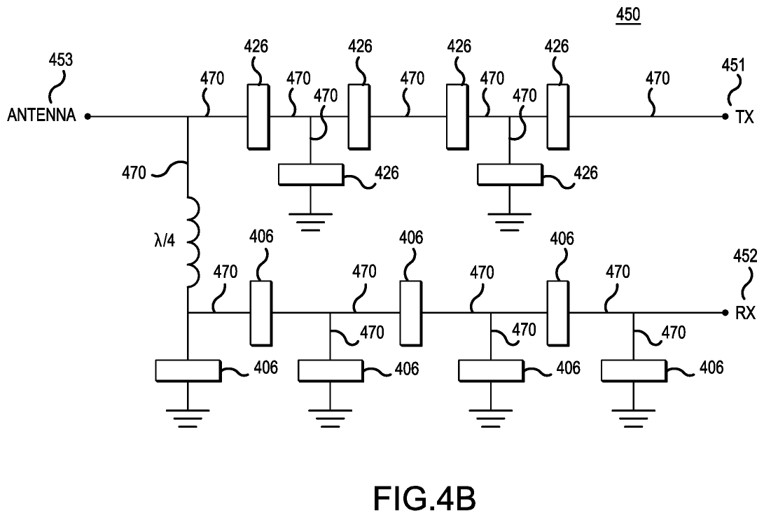

A first BAW resonator 106 is disposed over the first substrate 102 and the first acoustic reflector 104. The first BAW resonator 106 comprises a lower electrode 108, a piezoelectric layer 110, and an upper electrode 112. Illustratively, the first BAW resonator 106 comprises a bridge 114 on its connection side, and a cantilevered portion (“wing”) 115 on at least one other side. Notably, while only one BAW resonator is depicted as shown over the first substrate 102, a plurality of similar BAW resonators (not shown in FIG. 1A) are disposed over the first substrate 102, with a respective acoustic reflector disposed in the first substrate 102 beneath each BAW resonator. As will be shown below in connection with FIG. 4, the plurality of BAW resonators disposed over the first substrate 102 can be connected to form a resonator filter, which may be included in a duplexer or multiplexer. Moreover, one or more first BAW resonators 106 may be electrically connected to one or more second BAW resonators (e.g., second BAW resonators 126) disposed over another substrate (e.g., second substrate 122) to form a filter with connections made through the electrical conductors 170.

A second substrate 122 is disposed over the first substrate 102. A second acoustic reflector 124 is provided in the second substrate 122. Again, in certain embodiments (FBAR), the second acoustic reflector 124 is a cavity, and in other embodiments (SMR), the acoustic reflector is a distributed Bragg reflector comprising layers of alternating high acoustic impedance and low acoustic impedance materials.

A second BAW resonator 126 is disposed over the second substrate 122 and the second acoustic reflector 124. The second BAW resonator 126 comprises a lower electrode 128, a piezoelectric layer 130, and an upper electrode 132. Illustratively, the second BAW resonator 126 comprises a second bridge 134 on its connection side, and a cantilevered portion (“wing”) 135 on at least one other side. Notably, while only one BAW resonator is depicted as shown over the second substrate 122, a plurality of similar BAW resonators (not shown in FIG. 1A) are disposed over the second substrate 122, with a respective acoustic reflector disposed in the second substrate 122 beneath each BAW resonator. As will be shown below in connection with FIG. 4A, the plurality of BAW resonators disposed over the second substrate 122 can be connected to form a resonator filter, which may be included in a duplexer or multiplexer. Moreover, as alluded to above, one or more first BAW resonators 106 may be electrically connected to one or more second BAW resonators 126 disposed over the second substrate 122) to form a filter with connections made through the electrical conductors 170.

A first perimeter wall 142 extend between opposing inner surfaces 144, 146 of the first and second substrate 102, 122. The first perimeter wall 142 to provide separation between the first substrate and the second substrate, and as such, a first cavity 148 exists between opposing inner surfaces 144, 146 of the first substrate 102 and the second substrate 122. As will be appreciated, the first perimeter wall 142 is disposed along a prescribed perimeter of the first cavity 148.

The first perimeter wall 142 may be as described in commonly owned U.S. Pat. Nos. 7,642,642; 8,232,845; 8,280,080; 9,793,874; and 9,793,877. The disclosures of these patents are specifically incorporated herein by reference. Notably, the structure formed by the first substrate 102, the second substrate 122, and the first perimeter wall 142 may be referred to as a first microcap structure. Illustratively, the first perimeter wall 142 have a height “h” (z-direction in the coordinate system shown) of approximately 10.0 μm to approximately 70.0 μm, and a width “w” (x-direction in the coordinate system shown) of approximately 10.0 μmm to 200.0 μm. As described more fully below, with the first substrate 102 is bonded to the second substrate 122 along the first perimeter wall 142 substantially hermetic seal is provided and protects the various components in the first cavity 148 from ambient contaminants and debris.

A third substrate 152 is disposed over the second substrate 122. A second perimeter wall 162 extend between opposing inner surfaces 164, 166 of the second and third substrates 122, 152, respectively. The second perimeter wall 162 to provide separation between the first substrate and the second substrate, and as such, a second cavity 168 exists between opposing inner surfaces 144, 146 of the first substrate and the second substrate. As will be appreciated, the second perimeter wall 162 is disposed along a prescribed perimeter of the second cavity 168.

The second perimeter wall 162 may be as described in commonly owned U.S. Pat. Nos. 7,642,642; 8,232,845; 8,280,080; 9,793,874; and 9,793,877. The disclosures of these patents are specifically incorporated herein by reference. Notably, the structure formed by the second substrate 122, the third substrate 152, the second perimeter wall 162 may be referred to as a second microcap structure. Illustratively, the second perimeter wall 162 have a height “h” (z-direction in the coordinate system shown) of approximately 10.0 μm to approximately 70.0 μm, and a width “w” (x-direction in the coordinate system shown) of approximately 10.0 μmm to 200.0 μm. As described more fully below, with the third substrate 152 is bonded to the second substrate 122 along the second perimeter wall 162, a substantially hermetic seal is provided and protects the various components in the second cavity 168 from ambient contaminants and debris.

Electrical conductors 170 are provided in the first and second perimeter walls 142, 162, and selectively over other components of the electronic package 100 (e.g., the electrical conductors can be disposed over inner surfaces 144, 146, 164, 166) to provide electrical connections as needed for operation of the filters of the electronic package 100. In an embodiment, these electrical conductors 170 are selectively connected to contact pads 180 disposed over an outer surface 196 of the third substrate 152. An illustrative example of electrical connections between BAW resonators on two different substrates (e.g., first and second BAW resonators 106, 126) is shown and described in connection with FIG. 4B, below.

FIGS. 1B-1D are a cross-sectional view of a fabrication sequence of the electronic package of FIG. 1A, in accordance with a representative embodiment.

Turning to FIG. 1B, the first substrate 102 is shown with the first BAW resonator 106 disposed thereover. Similarly, the second substrate 122 is shown with the second BAW resonator 126 disposed thereover.

As alluded to above, the fabrication of the first and second BAW resonators 106, 126 and various features thereof are effected using known methods and materials as described in one or more of the above-incorporated patents and patent application publications. Illustratively, the first and second substrates 102, 122 comprise silicon (Si) or other suitable materials disclosed in one or more of the above-incorporated patents and patent application publications.

At this stage of fabrication, the first and second BAW resonators 106, 126 have been fine tuned by known technique to a desired frequency. Tuning is effected by a well-known technique to tune each BAW resonator of a particular circuit (e.g., filter) of a representative embodiment to a targeted frequency before the first and second substrates 102, 122 are bonded together. As such, the combined circuit stacks of the final electronic package 100 require no further tuning after bonding is completed.

The third substrate 152 is shown after formation of the electrical conductors 170 disposed therein. The second perimeter wall 162 and second cavity 160 are formed by etching of the third substrate 152, using, for example, a known etching method, such as by deep reactive ion etching to provide a comparatively high aspect ratio etch (e.g., the Bosch Method). Alternative known etching methods to include known wet etching methods are also contemplated for forming the second cavity 160. By way of illustration, the second cavity 160 has a depth (z-direction in the coordinate system shown) in the range of approximately 10 μm to approximately 30 μm.

The electrical conductors 170 and the contact pads 180 are formed in and over the first, second and third substrates 102, 122, 152 as shown. These electrical conductors 170 comprise a suitably electrically conductive material (e.g., Au) or other suitable. Notably, vias 190, 192 are first formed the second and third substrates 122, 152, respectively. These vias 190, 192 are then filled with suitable electrically conductive material to form the electrical conductors 170 therein. The methods and materials used to form the vias 190, 192 and electrical conductors 170 and contact pads are known and may be as disclosed in one or more of the above-incorporated patents and patent application publications.

Turning to FIG. 1C, the first, second and third substrates 102, 122, 152 are shown after further processing. To this end, after formation of the electrical conductors 170 and the second cavity 160, the first substrate 102 is back-grinded or otherwise etched to have a desired thickness (z-dimension in the coordinate system of FIG. 1C). Similarly, the second cavity 160 is formed by etching the second substrate 122 using a known etching method, such as by deep reactive ion etching to provide a comparatively high aspect ratio etch (e.g., the Bosch Method). to a depth z-dimension in the coordinate system of FIG. 1C of 10 μm to approximately 30 μm. Prior to bonding the first, second and third substrates 102, 122, 152 together, a final tuning of the first and second BAW resonators 106, 126 is effected to a final targeted frequency.

FIG. 1D depicts the bonding of the first, second and third substrates 102, 122, 152 to form the electronic package 100. In a representative embodiment, the bonding is effected using known methods and materials, such as described in one or more of the above-incorporated patents and patent application publications. To this end, a known “microcap” bonding method such as a metal-metal (or alloys) bonding at comparatively high pressure and elevated temperature may be used. Alternative known methods such as polymer-polymer bonding can be effected with suitable polymer layers (e.g., benzocycolbutene (BCB) or polyimide) by disposing the polymer in appropriate positions and curing the polymer layers together at a slightly elevated bonding temperature.. To this end, adhesion of the first, second and third substrates 102, 122, 152 realized by the bonding of the electrical conductors 170 of the first and second perimeter walls 142, 162, at their points of contact with the electrical conductors 170 disposed over the upper surfaces of the first and second substrates 102, 122, respectively. The bonding of the first, second and third substrates 102, 122, 152 forms a substantially hermetic seal along the first and second perimeter walls 142, 162, and results in the first and second cavities' 148, 160 being substantially hermetically sealed.

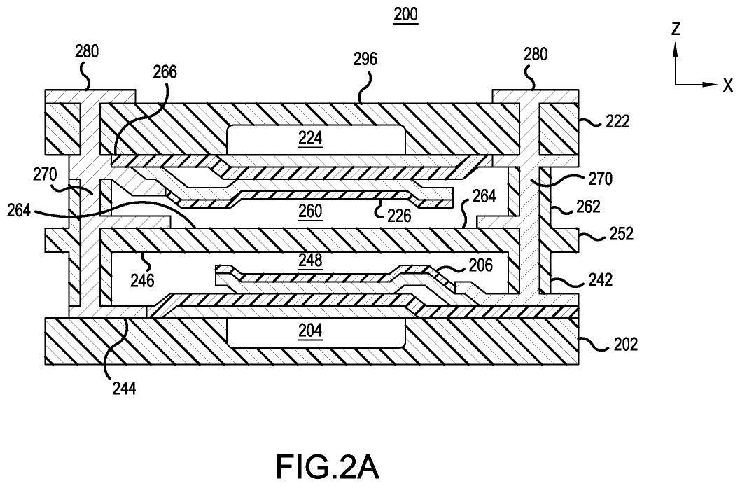

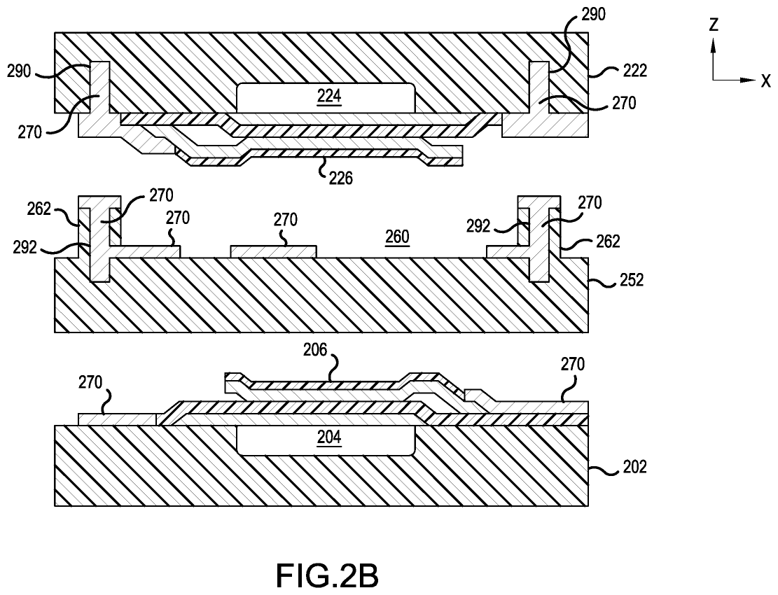

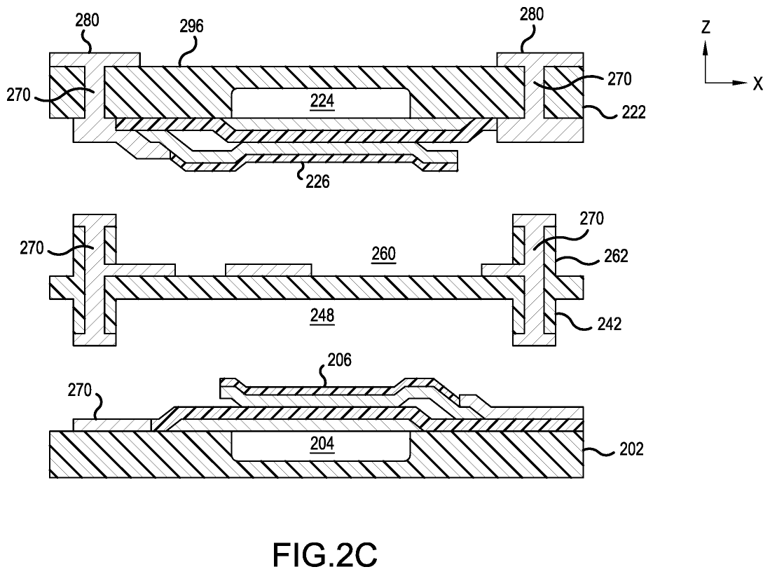

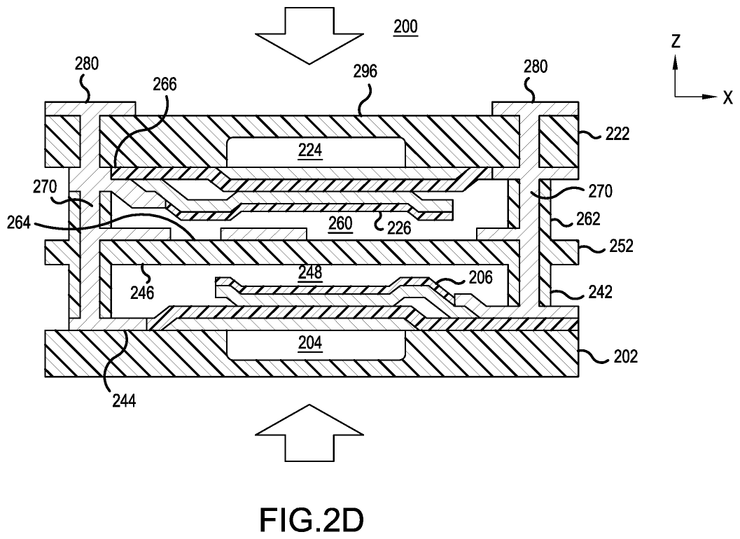

FIG. 2A is a cross-sectional view of an electronic package 200 in accordance with a representative embodiment. As will be appreciated, many of the details of the description of the electronic package 200 are similar to those of the electronic package 100, and may be omitted to avoid obscuring the presently described representative embodiments.

The electronic package comprises a first substrate 202, with a first acoustic reflector 204 disposed therein. In certain embodiments (FBAR), the first acoustic reflector 204 is a cavity, and in other embodiments (SMR), the acoustic reflector is a distributed Bragg reflector comprising layers of alternating high acoustic impedance and low acoustic impedance materials.

A first BAW resonator 206 is disposed over the first substrate 202 and the first acoustic reflector 204. Notably, while only one BAW resonator is depicted as shown over the first substrate 202, a plurality of similar BAW resonators (not shown in FIG. 2A) are disposed over the first substrate 202, with a respective acoustic reflector disposed in the first substrate 202 beneath each BAW resonator. As will be shown below in connection with FIG. 4, the plurality of BAW resonators disposed over the first substrate 202 can be connected to form a resonator filter, which may be included in a duplexer or multiplexer. Moreover, one or more first BAW resonators 206 may be electrically connected to one or more second BAW resonators (e.g., second BAW resonators 226) disposed over another substrate (e.g., second substrate 222) to form a filter with connections made through the electrical conductors 270.

A second substrate 222 is disposed over the first substrate 102. A second acoustic reflector 224 is provided in the second substrate 222. Again, in certain embodiments (FBAR), the second acoustic reflector 224 is a cavity, and in other embodiments (SMR), the acoustic reflector is a distributed Bragg reflector comprising layers of alternating high acoustic impedance and low acoustic impedance materials.

A second BAW resonator 226 is disposed over the second substrate 222 and the second acoustic reflector 224. Notably, while only one BAW resonator is depicted as shown over the second substrate 222, a plurality of similar BAW resonators (not shown in FIG. 2A) are disposed over the second substrate 222, with a respective acoustic reflector disposed in the second substrate 222 beneath each BAW resonator. As will be shown below in connection with FIG. 4, the plurality of BAW resonators disposed over the second substrate 222 can be connected to form a resonator filter, which may be included in a duplexer or multiplexer. Moreover, as alluded to above one or more first BAW resonators 206 may be electrically connected to one or more second BAW resonators 226 disposed over the second substrate 222 to form a filter with connections made through the electrical conductors 270.

A third substrate 252 is disposed over the second substrate 222, and between the first substrate 202 and the second substrate 222.

A first perimeter wall 242 extend between opposing inner surfaces 244, 246 of the first and third substrates 202, 252. The first perimeter wall 242 to provide separation between the first substrate 202 and the third substrate 252, and as such, a first cavity 248 exists between opposing inner surfaces 244, 246 of the first substrate and the second substrate.

A second perimeter wall 262 extend between opposing inner surfaces 264, 266 of the second and third substrates 222, 252, respectively. The second perimeter wall 262 provide separation between the second substrate 222 and the third substrate 252, and as such, a second cavity 268 exists between opposing inner surfaces 244, 246 of the second substrate 222 and the third substrate 252.

The first and second perimeter walls 242, 262 may be as described in commonly owned and above-incorporated U.S. Pat. Nos. 7,642,642; 8,232,845; 8,280,080; 9,793,874; and 9,793,877. Notably, the structure formed by the first substrate 202, the third substrate 252, and the first perimeter wall 242 may be referred to as a first microcap structure. Similarly, the structure formed by the second substrate 222, the third substrate 252, and the second perimeter wall 262 may be referred to as a second microcap structure. Illustratively, the first and second perimeter walls 242,262 have a height “h” (z-direction in the coordinate system shown) of approximately 10.0 μm to approximately 70.0 μm, and a width “w” (x-direction in the coordinate system shown) of approximately 10.0 μmm to 200.0 μm. As described more fully below, with the first substrate 202 is bonded to the third substrate 252 along the first perimeter wall 242 a substantially hermetic seal is provided, and thereby protect the various components in the first cavity 248 from ambient contaminants and debris. Similarly, the second substrate 222 is bonded to with the third substrate 252 along the second perimeter wall 262 to provide a substantially hermetic seal and to protect the various components in the second cavity 168 from ambient contaminants and debris.

Electrical conductors 270 are provided in the first and second perimeter walls 242, 262, and selectively over other components of the electronic package 200 (e.g., the electrical conductors can be disposed over inner surfaces 244, 246, 264, 266) to provide electrical connections as needed for operation of the filters of the electronic package 200. In an embodiment, these electrical conductors 270 are selectively connected to contact pads 280 disposed over an outer surface 296 of the second substrate 222. (For example, as depicted in FIGS. 4A, 4B discussed below.)

FIGS. 2B-2D are a cross-sectional view of a fabrication sequence of the electronic package of FIG. 2A, in accordance with a representative embodiment.

Turning to FIG. 2B, the first substrate 202 is shown with the first BAW resonator 206 disposed thereover. Similarly, the second substrate 222 is shown with the second BAW resonator 226 disposed thereover.

As noted above, the fabrication of the first and second BAW resonators 206, 226 and various features thereof are effected using known methods and materials as described in one or more of the above-incorporated patents and patent application publications. Illustratively, the first and second substrates 202, 222 comprises silicon (Si) or other suitable materials disclosed in one or more of the above-incorporated patents and patent application publications. At this stage of fabrication, the first and second BAW resonators 206, 226 have been fine tuned by known technique to a desired frequency as described above.

The third substrate 252 is shown after formation of the electrical conductors 270 disposed therein. The second perimeter wall 262 and second cavity 260 are formed by etching of the third substrate 252, using, for example, a known etching method, such as by deep reactive ion etching to provide a comparatively high aspect ratio etch (e.g., the Bosch Method). Alternative known etching methods to include known wet etching methods are also contemplated for forming the third cavity. By way of illustration, as noted above, the second cavity 260 has a depth (z-direction in the coordinate system shown) in the range of approximately 10 μm to approximately 30 μm.

The electrical conductors 270 are formed in and over the first, second and third substrates 202, 222, 252 as shown. These electrical conductors 270 comprise a suitably electrically conductive material (e.g., Au) or other suitable. Notably, vias 290, 292 are first formed the second and third substrates 222, 252, respectively. These vias 290, 292 are then filled with suitable electrically conductive material to form the electrical conductors 270 therein. The methods and materials used to form the vias 290, 292 and electrical conductors 270 are known, and may be as disclosed in one or more of the above-incorporated patents and patent application publications.

Turning to FIG. 2C, the first, second and third substrates 202, 222, 252 are shown after further processing. To this end, after formation of the electrical conductors 270 and the second cavity 260, the first substrate 202 is back-grinded or otherwise etched to have a desired thickness (z-dimension in the coordinate system of FIG. 2C). Similarly, the second cavity 260 is formed by etching the second substrate 222 using a known etching method, such as by deep reactive ion etching to provide a comparatively high aspect ratio etch (e.g., the Bosch Method) to a depth (z-dimension in the coordinate system of FIG. 2C) of approximately 10 μm to approximately 30 μm. Moreover, as depicted, contact pads 280 are disposed over an outer surface of the second substrate. Prior to bonding the first, second and third substrates 202, 222, 252 together, a final tuning of the first and second BAW resonators 206, 226 is effected to a final targeted frequency.

FIG. 2D depicts the bonding of the first, second and third substrates 202, 222, 252 to form the electronic package 200. In a representative embodiment, the bonding is effected using known methods and materials, such as described in one or more of the above-incorporated patents and patent application publications by known metal-metal bonding or polymer-polymer bonding as discussed more fully above. To this end, adhesion of the first, second and third substrates 202, 222, 252 realized by the bonding of the electrical conductors 270 of the first and second perimeter walls 242, 262, at their points of contact with the electrical conductors 170 disposed over the upper surfaces of the first and second substrates 202, 222, respectively. The bonding of the first, second and third substrates 202, 222, 252 forms a substantially hermetic seal along the first and second perimeter walls 242,262, and results in the first and second cavities' 248, 260 being substantially hermetically sealed.

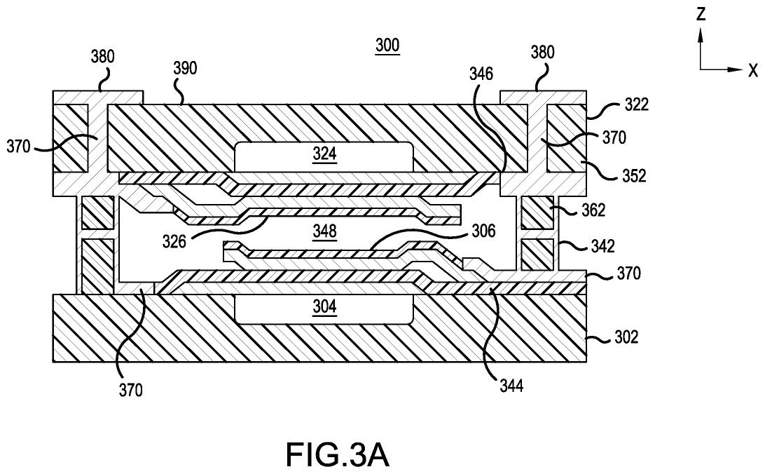

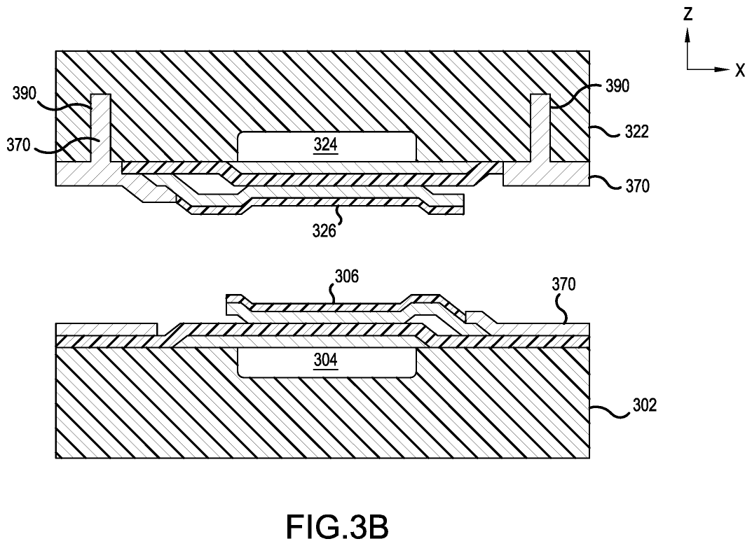

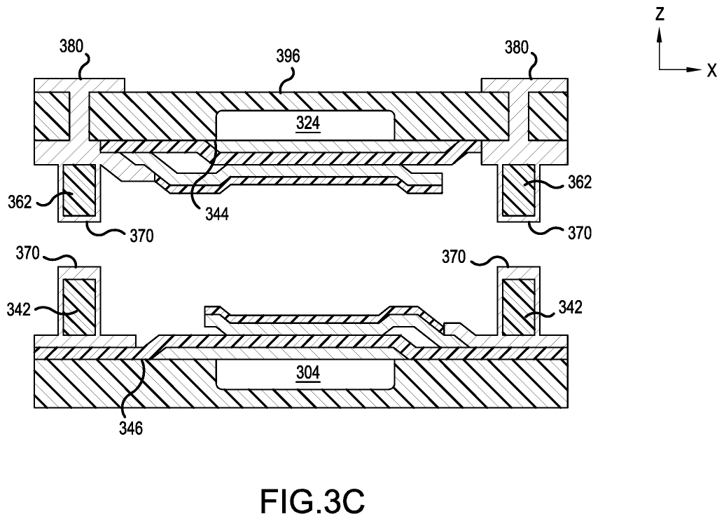

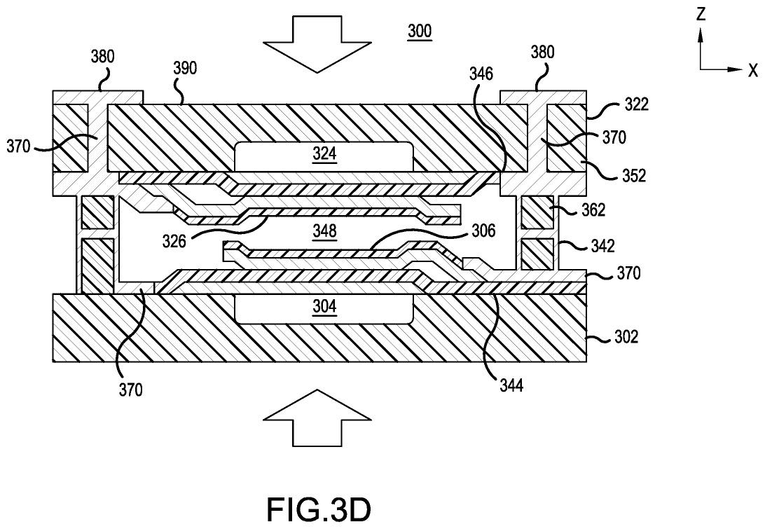

FIG. 3A is a cross-sectional view of an electronic package 300 in accordance with a representative embodiment. As will be appreciated, many of the details of the description of the electronic package 300 are similar to those of the electronic packages 100, 200, and may be omitted to avoid obscuring the presently described representative embodiments.

The electronic package comprises a first substrate 302, with a first acoustic reflector 304 disposed therein. In certain embodiments (FBAR), the first acoustic reflector 304 is a cavity, and in other embodiments (SMR), the acoustic reflector is a distributed Bragg reflector comprising layers of alternating high acoustic impedance and low acoustic impedance materials.

A first BAW resonator 306 is disposed over the first substrate 302 and the first acoustic reflector 204. Notably, while only one BAW resonator is depicted as shown over the first substrate 302, a plurality of similar BAW resonators (not shown in FIG. 3A) are disposed over the first substrate 302, with a respective acoustic reflector disposed in the first substrate 302 beneath each BAW resonator. As will be shown below in connection with FIG. 4, the plurality of BAW resonators disposed over the first substrate 302 can be connected to form a resonator filter, which may be included in a duplexer or multiplexer. Moreover, one or more first BAW resonators 306 may be electrically connected to one or more second BAW resonators (e.g., second BAW resonators 326) disposed over another substrate (e.g., second substrate 322) to form a filter with connections made through the electrical conductors 370.

A second substrate 322 is disposed over the first substrate 202. A second acoustic reflector 324 is provided in the second substrate 222. Again, in certain embodiments (FBAR), the second acoustic reflector 224 is a cavity, and in other embodiments (SMR), the acoustic reflector is a distributed Bragg reflector comprising layers of alternating high acoustic impedance and low acoustic impedance materials.

A second BAW resonator 226 is disposed over the second substrate 222 and the second acoustic reflector 224. Notably, while only one BAW resonator is depicted as shown over the second substrate 222, a plurality of similar BAW resonators (not shown in FIG. 2A) are disposed over the second substrate 222, with a respective acoustic reflector disposed in the second substrate 222 beneath each BAW resonator. As will be shown below in connection with FIG. 4, the plurality of BAW resonators disposed over the second substrate 222 can be connected to form a resonator filter, which may be included in a duplexer or multiplexer. Moreover, as alluded to above, one or more first BAW resonators 306 may be electrically connected to one or more second BAW resonators 326 disposed over the second substrate 322 to form a filter with connections made through the electrical conductors 370.

A first perimeter wall 342 extends between from inner surface 344 of the first substrate 302. The first perimeter wall 342 to provide separation between the first substrate 302 and the second substrate 322.

A second perimeter wall 362 extends between opposing inner surfaces 344, 346 of the first and second substrates 302, 322, respectively. The second perimeter wall 362 provide further separation between the first substrate 302 and the second substrate 322, and as such, a cavity 348 exists between opposing inner surfaces 344, 346 of the first substrate 302 and the second substrate 322.

As described more fully below, unlike the first and second perimeter walls of the electronic packages 100, 200 described above, which are generally made of the same material as the second and third substrates 322, 352 described above, the first and second perimeter walls 342, 362 of the representative embodiment of FIG. 3A are made from a material different than that of the first and second substrates 302, 322.

Notably, the structure formed by the first substrate 302, the second substrate 322, and the first and second perimeter walls 342, 362 may be referred to as a microcap structure.

Illustratively, the first and second perimeter walls 342, 362 each have a height “h” (z-direction in the coordinate system shown) of approximately 10.0 μm to approximately 70.0 m, and a width “w” (x-direction in the coordinate system shown) of approximately 10.0 μmm to 200.0 μm. In a representative embodiment, the first and second perimeter walls 342,362 each have a height “h” of approximately 10.0 As described more fully below, with the first substrate 202 is bonded to the third substrate 252 μm, and each have a width “w” of approximately 10.0 μm. Like the first and second perimeter walls of the embodiments depicted in FIGS. 1A-2D, bonding of the first and second substrates 302,322 by first and second perimeter walls 342,362, respectively, provide a substantially hermetic seal around the cavity, and thereby protect the various components in the cavity 348 from ambient contaminants and debris.

Electrical conductors 370 are provided over, and encapsulate the first and second perimeter walls 342, 362 as shown. The electrical conductors 370 are also disposed selectively over other components of the electronic package 300 (e.g., the electrical conductors can be disposed over inner surfaces 344, 346) to provide electrical connections as needed for operation of the filters of the electronic package 300 (for example, as depicted in FIG. 4A, discussed below). In an embodiment, these electrical conductors 370 are selectively connected to contact pads 380 disposed over an outer surface 396 of the second substrate 222.

Turning to FIG. 3B, the first substrate 302 is shown with the first BAW resonator 306 disposed thereover. Similarly, the second substrate 322 is shown with the second BAW resonator 326 disposed thereover.

As noted above, the fabrication of the first and second BAW resonators 306, 326 and various features thereof are effected using known methods and materials as described in one or more of the above-incorporated patents and patent application publications. Illustratively, the first and second substrates 302, 322 comprises silicon (Si) or other suitable materials such as disclosed in one or more of the above-incorporated patents and patent application publications. At this stage of fabrication, the first and second BAW resonators 306, 326 have been fine tuned by known technique to a desired frequency as described above.

The electrical conductors 370 are formed in and over the first and second substrates 302, 322 as shown. These electrical conductors 370 comprise a suitably electrically conductive material (e.g., Au) or other suitable. Notably, vias 390 are first formed the second substrate 322. These vias 390 are then filled with suitable electrically conductive material to form the electrical conductors 370 therein. The methods and materials used to form the vias 390 and electrical conductors 370 are known, and may be as disclosed in one or more of the above-incorporated patents and patent application publications.

Turning to FIG. 3C, the first and second substrates 302, 322 are shown after further processing. To this end, after formation of the electrical conductors 270, the first substrate 302 is back-grinded to have a desired thickness (z-dimension in the coordinate system of FIG. 3C). Prior to bonding the first and second substrates 302, 322 together, a final tuning of the first and second BAW resonators 306, 326 is effected to a final targeted frequency.

Moreover, as shown in FIG. 3C, the first and second perimeter walls 342, 362 are shown after formation over the first and second substrates 302,322, respectively. In accordance with a representative embodiment, the first and second perimeter walls 342, 362 are made of a polymer material such as benzocyclobutane (BCB) or other suitable material. A comparatively thick (z-direction in the coordinate system of FIG. 3C) layer of material is deposited over the respective inner surfaces 344, 364 as shown. In a representative embodiment, the material has a thickness of approximately 20.0 μm. After the material is cured, material to form the electrical conductors 370 over the first and second perimeter walls 342,362. Notably, the first and second perimeter walls 342,362 may be patterned to form not only bonding surfaces at their points of contact, but also conductive vias (not shown) that extend through the respective first and second perimeter walls 342, 356. These conductive vias may effect electrical connections between the components (e.g., BAW resonators and passive electrical devices (not shown) on the different substrates (first and second substrate 302, 322, for example).

FIG. 3D depicts the bonding of the first and second substrates 302, 322 to form the electronic package 300. In a representative embodiment, the bonding is effected using known methods and materials, such as described in one or more of the above-incorporated patents and patent application publications. In a particular representative embodiment, the bonding is effected using a known polymer-polymer bonding technique known to one of ordinary skill in the art. To this end, adhesion of the first and second substrates 302, 322 realized by the bonding of the electrical conductors 370 of the first and second perimeter walls 342, 362, at their points of contact. The bonding of the first and second substrates 302, 322, forms a substantially hermetic seal along the first and second perimeter walls 342, 362, and results in the cavity 348 being substantially hermetically sealed.

FIG. 4A is a top view depicting the layout of a BAW resonator filter 400 disposed over a substrate 402, in accordance with a representative embodiment. As will be appreciated, many of the details of the description of the BAW resonator filter 400 are similar to those described in connection with the representative embodiments of FIGS. 1A-3D, and may be omitted to avoid obscuring the presently described representative embodiments.

The BAW resonator filter 400 comprises a plurality of BAW resonators 406 disposed over a substrate 402, and connected in a desired fashion to form a desired filter. For example, the BAW resonators 406 may be connected together by the electrical conductors 470 in series and shunt arrangements to provide ladder or lattice filters. As noted above, a plurality of BAW resonators can be selectively electrically connected for use in a duplexer or multiplexer.

As will be appreciated, in accordance with a representative embodiment, the plurality of BAW resonators may form the BAW resonators disposed over one of the substrates described above. As such, each substrate may include a filter. Alternatively, BAW resonators 406 may be electrically connected to BAW resonators disposed over another substrate (e.g., first and second substrates 102,122 described above) to form a filter.

Finally, for perspective, the perimeter wall (not shown) formed between two substrates as discussed above would be formed over an upper surface of the substrate 402, or would be in contact with the upper surface of the substrate 402.

FIG. 4B is a simplified schematic diagram of a filter arrangement 450 for a duplexer in accordance with a representative embodiment. As will be appreciated, many of the details of the description of the filter 450 are similar to those described in connection with the representative embodiments of FIGS. 1A-4A and may be omitted to avoid obscuring the presently described representative embodiments.

In a representative embodiment, the filter arrangement 450 is a filter for duplex for transmission and reception. A transmit input 451, and a receive input 452, are configured to transmit signals and receive signals, respectively, via an antenna 453. The transmit and receive inputs 451, 452 are connected to other circuitry (not shown), such as a power amplifier.

The receive branch of the filter arrangement 450 comprises BAW resonators 406 is a series and shunt configuration as shown, with electrical connections made between the respective BAW resonators 406 by electrical conductors 470. Just by way of example, the receive branch of the filter arrangement 450 be disposed on first substrates 102, 202, 302 with the BAW resonators 406 corresponding the first BAW resonators 106, 206, 306, respectively. In such an arrangement, electrical conductors 470 would correspond to electrical conductors 170, 270, 370, respectively.

The transmit branch of the filter arrangement 450 comprises BAW resonators 426 is a series and shunt configuration as shown, and disposed between the transmit input and the antenna. Electrical connections made between the respective BAW resonators 426 by electrical conductors 470. Just by way of example, the transmit branch of the filter arrangement 450 be disposed on second substrates 122,222 and 422 with the BAW resonators 426 corresponding the second BAW resonators 126, 226, 326, respectively. In such an arrangement, electrical conductors 470 would correspond to electrical conductors 170, 270, 370, respectively.

Finally, the connections between the transmit and receive branches of the filter arrangement 450 are made by electrical connections 470 as shown. As will be appreciated, the electrical connections between the transmit and receive branches of the filter arrangement 450 correspond, for example, to the electrical conductors 170, 270, 370 between the respective first substrates 102, 202, 302 and second substrates 122, 222, 322 shown in the representative embodiments of FIGS. 1A, 2A and 3A.

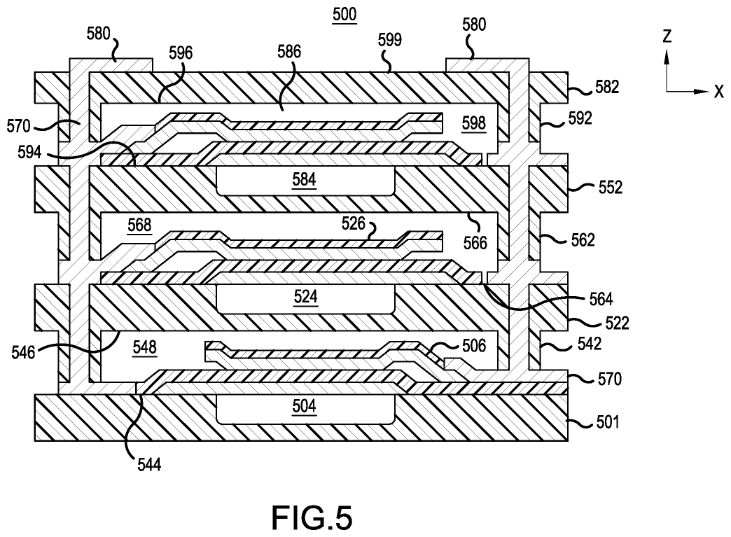

FIG. 5 is a cross-sectional view of an electronic package 500 in accordance with a representative embodiment. The electronic package 500 expands on the principles of vertical integration and packaging described above in accordance with the present teachings.

As will be appreciated, many of the details of the description of the electronic package 500 are similar to those of the electronic packages 100-300 and the filter arrangement 450 described above, and may be omitted to avoid obscuring the presently described representative embodiments.

The electronic package 500 comprises a first substrate 502, with a first acoustic reflector 504 disposed therein. In certain embodiments (FBAR), the first acoustic reflector 504 is a cavity, and in other embodiments (SMR), the acoustic reflector is a distributed Bragg reflector comprising layers of alternating high acoustic impedance and low acoustic impedance materials.

A first BAW resonator 506 is disposed over the first substrate 502 and the first acoustic reflector 504. Notably, while only one BAW resonator is depicted as shown over the first substrate 502, a plurality of similar BAW resonators (not shown in FIG. 5) are disposed over the first substrate 502, with a respective acoustic reflector disposed in the first substrate 502 beneath each BAW resonator. As shown and described in connection with FIG. 4A, the plurality of BAW resonators disposed over the first substrate 502 can be connected to form a resonator filter, which may be included in a duplexer or multiplexer. Moreover, one or more first BAW resonators 506 may be electrically connected to one or more second BAW resonators (e.g., second BAW resonators 526) disposed over another substrate (e.g., second substrate 522) to form a filter with connections made through the electrical conductors 570.

A second substrate 522 is disposed over the first substrate 502. A second acoustic reflector 524 is provided in the second substrate 522. Again, in certain embodiments (FBAR), the second acoustic reflector 524 is a cavity, and in other embodiments (SMR), the acoustic reflector is a distributed Bragg reflector comprising layers of alternating high acoustic impedance and low acoustic impedance materials.

A second BAW resonator 526 is disposed over the second substrate 522 and the second acoustic reflector 524. Notably, while only one BAW resonator is depicted as shown over the second substrate 522, a plurality of similar BAW resonators (not shown in FIG. 5) are disposed over the second substrate 522, with a respective acoustic reflector disposed in the second substrate 522 beneath each BAW resonator. As will be shown above in connection with FIG. 4A, the plurality of BAW resonators disposed over the second substrate 522 can be connected to form a resonator filter, which may be included in a duplexer or multiplexer. Moreover, as described above in connection with FIG. 4B, one or more first BAW resonators 506 may be electrically connected to one or more second BAW resonators 526 disposed over the second substrate 522 to form a filter with connections made through the electrical conductors 570.

A third substrate 552 is disposed over the second substrate 522. A third BAW resonator 586 is disposed over the third substrate 552 and the third acoustic reflector 584. Notably, while only one BAW resonator is depicted as shown over the third substrate 552, a plurality of similar BAW resonators (not shown in FIG. 5) are disposed over the third substrate 552, with a respective acoustic reflector disposed in the third substrate 552 beneath each BAW resonator. As described above in connection with FIG. 4A, the plurality of BAW resonators disposed over the third substrate 552 can be connected to form a resonator filter, which may be included in a duplexer or multiplexer. Moreover, as described in connection with FIG. 4B, BAW resonators on different substrates may be connected through electrical conductors 570. As such, one or more third BAW resonators 586 may be electrically connected to one or more second BAW resonators 526 disposed over the second substrate 522, and with one or more first BAW resonators 506 disposed over the first substrate 502 to form a filter with connections made through the electrical conductors 570.

A fourth substrate 582 is disposed over the third substrate 552.

A first perimeter wall 542 extends between opposing inner surfaces 544, 546 of the first and second substrate 502, 522. The first perimeter wall 542 to provide separation between the first substrate and the second substrate, and as such, a first cavity 548 exists between opposing inner surfaces 544, 546 of the first substrate 502 and the second substrate 522. As will be appreciated, the first perimeter wall 542 is disposed along a prescribed perimeter of the first cavity 548.

A second perimeter wall 562 extends between opposing inner surfaces 564, 566 of the second and third substrates 522, 552, respectively. The second perimeter wall 562 provide separation between the second substrate 522 and the third substrate 552, and as such, a second cavity 568 exists between opposing inner surfaces 544, 546 of the second substrate 522 and the third substrate 552.

A third perimeter wall 592 extends between opposing inner surfaces 594, 596 of the third and fourth substrates 552, 582, respectively. The third perimeter wall 592 provides separation between the third substrate 552 and the fourth substrate 582, and as such, a third cavity 598 exists between opposing inner surfaces 594, 586 of the third substrate 552 and fourth substrate 582, respectively. Notably, the structure formed by the third substrate 552, the fourth substrate 582, the third perimeter wall 592 may be referred to as a third microcap structure.

The first-third perimeter walls 542, 562, 592 may be as described in commonly owned U.S. Pat. Nos. 7,642,642; 8,232,845; 8,280,080; 9,793,874; and 9,793,877. The disclosures of these patents are specifically incorporated herein by reference. Illustratively, the first-third perimeter walls 542, 562, 592 each have a height “h” (z-direction in the coordinate system shown) of approximately 10.0 μm to approximately 70.0 μm, and a width “w” (x-direction in the coordinate system shown) of approximately 10.0 μmm to 200.0 μm. As described more fully below, bonding of the first substrate 502, the second substrate 522, and the third substrate 552, respective substantially hermetic seals are provided and protects the various components in the first cavity 548, the second cavity 568 and the third cavity 598 from ambient contaminants and debris.

Electrical conductors 570 are provided in the first-third perimeter walls 542, 562, 593, and selectively over other components of the electronic package 500 (e.g., the electrical conductors can be disposed over inner surfaces 444, 546, 564, 566, 594,596) to provide electrical connections as needed for operation of the filters of the electronic package 100. In an embodiment, these electrical conductors 570 are selectively connected to contact pads 580 disposed over an outer surface 599 of the fourth substrate 582. An illustrative example of electrical connections between BAW resonators on two different substrates (e.g., BAW first and second resonators 526, 586) is shown and described in connection with FIG. 4B, above.

Fabrication of the electronic package 500 is effected in substantively identical ways to those described above in connection with FIGS. 1A-3D. Notably, the first, second and third BAW resonators 506, 526 and 586 are fabricated over respective first, second and third acoustic reflectors 504, 524, 584 disposed in the first, second and third substrates 502, 522, 552, respectively. Selective removal of portions of the first, second, third substrates and fourth substrates 502, 522, 552, 582 is done by etching and grinding methods described above to reveal first, second and third cavities 548, 568 and 598, and to provide the proper thickness (z-direction in the coordinate system of FIG. 5) of selected substrates. Next, the first, second and third BAW resonators 506, 526 and 586 are tuned. After tuning, the first and second substrates 502, 522 may be bonded along the first perimeter wall 542 by a metal/allow-metal/alloy bonding technique noted above, or by a polymer-polymer technique described above. Similarly, the third substrate 552 and the fourth substrate 582 may be bonded along the third perimeter wall 592 by a metal/allow-metal/alloy bonding technique noted above, or by a polymer-polymer technique described above. Finally, these structures are bonded together along the interface of the inner surface 564 and the second perimeter wall 562 by a metal/allow-metal/alloy bonding technique noted above, or by a polymer-polymer technique described above.

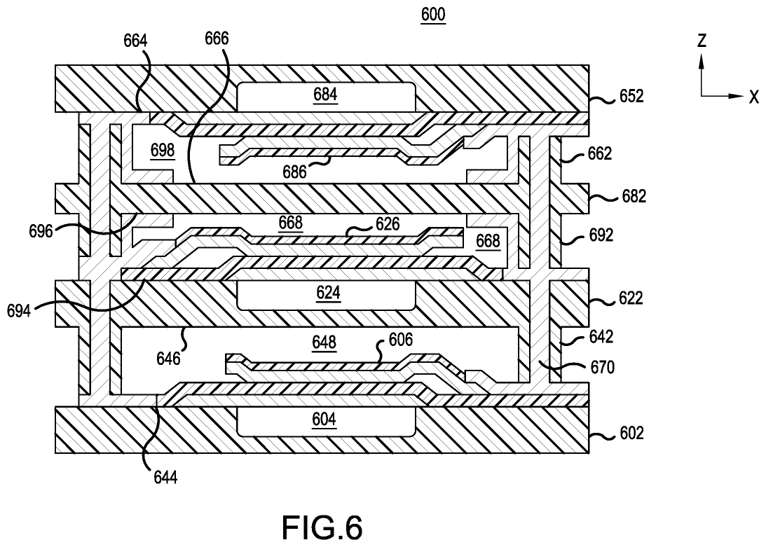

FIG. 6 is a cross-sectional view of an electronic package 600 in accordance with a representative embodiment. As will be appreciated, many of the details of the description of the electronic package 600 are similar to those of the electronic packages 100-300, 500, and the filter arrangement 450 described above, and may be omitted to avoid obscuring the presently described representative embodiments.

The electronic package 600 comprises a first substrate 602, with a first acoustic reflector 604 disposed therein. In certain embodiments (FBAR), the first acoustic reflector 604 is a cavity, and in other embodiments (SMR), the acoustic reflector is a distributed Bragg reflector comprising layers of alternating high acoustic impedance and low acoustic impedance materials.

A first BAW resonator 606 is disposed over the first substrate 602 and the first acoustic reflector 604. Notably, while only one BAW resonator is depicted as shown over the first substrate 602, a plurality of similar BAW resonators (not shown in FIG. 6) are disposed over the first substrate 602, with a respective acoustic reflector disposed in the first substrate 602 beneath each BAW resonator. As shown and described in connection with FIG. 4A, the plurality of BAW resonators disposed over the first substrate 602 can be connected to form a resonator filter, which may be included in a duplexer or multiplexer. Moreover, one or more first BAW resonators 606 may be electrically connected to one or more second BAW resonators (e.g., second BAW resonators 626) disposed over another substrate (e.g., second substrate 622) to form a filter with connections made through the electrical conductor 670.

A second substrate 622 is disposed over the first substrate 602. A second acoustic reflector 624 is provided in the second substrate 622. Again, in certain embodiments (FBAR), the second acoustic reflector 624 is a cavity, and in other embodiments (SMR), the acoustic reflector is a distributed Bragg reflector comprising layers of alternating high acoustic impedance and low acoustic impedance materials.

A second BAW resonator 626 is disposed over the second substrate 622 and the second acoustic reflector 624. Notably, while only one BAW resonator is depicted as shown over the second substrate 622, a plurality of similar BAW resonators (not shown in FIG. 6) are disposed over the second substrate 622, with a respective acoustic reflector disposed in the second substrate 622 beneath each BAW resonator. As will be shown above in connection with FIG. 4A, the plurality of BAW resonators disposed over the second substrate 622 can be connected to form a resonator filter, which may be included in a duplexer or multiplexer. Moreover, described in connection with FIG. 4B, one or more first BAW resonators 606 may be electrically connected to one or more second BAW resonators 626 disposed over the second substrate 622 to form a filter with connections made through the electrical conductor 670.

A fourth substrate 682 is disposed over the second substrate 652.

A third substrate 652 is disposed over the fourth substrate 682. A third BAW resonator 686 is disposed over the third substrate 652 and the third acoustic reflector 684. Notably, while only one BAW resonator is depicted as shown over the third substrate 652, a plurality of similar BAW resonators (not shown in FIG. 6) are disposed over the third substrate 652, with a respective acoustic reflector disposed in the third substrate 652 beneath each BAW resonator. As described above in connection with FIG. 4A, the plurality of BAW resonators disposed over the third substrate 652 can be connected to form a resonator filter, which may be included in a duplexer or multiplexer. Moreover, as described in connection with FIG. 4B one or more third BAW resonators 686 may be electrically connected to one or more second BAW resonators 626 disposed over the second substrate 622, and with one or more first BAW resonators 506 disposed over the first substrate 602 to form a filter with connections made through the electrical conductor 670.

A first perimeter wall 642 extends between opposing inner surfaces 644, 646 of the first and second substrate 602, 622. The first perimeter wall 642 to provide separation between the first substrate and the second substrate, and as such, a first cavity 648 exists between opposing inner surfaces 644, 646 of the first substrate 602 and the second substrate 622. As will be appreciated, the first perimeter wall 642 is disposed along a prescribed perimeter of the first cavity 648.

A second perimeter wall 662 extends between opposing inner surfaces 664, 666 of the third and fourth substrates 652, 682, respectively. The second perimeter wall 662 provides separation between the third substrate 652 and the fourth substrate, and as such, a second cavity 668 exists between opposing inner surfaces 664, 666 of the third substrate 652 and fourth substrate 682.

A third perimeter wall 692 extends between opposing inner surfaces 694, 696 of the second and fourth substrates 622,682, respectively. The third perimeter wall 692 provides separation between the second substrate 622 and the fourth substrate 682, and as such, a second cavity 668 exists between opposing inner surfaces 694, 696 of the second substrate 622 and fourth substrate 682, respectively. Notably, the structure formed by the second substrate 622, the fourth substrate 682, and the third perimeter wall 692 may be referred to as a third microcap structure.

The first-third perimeter walls 642, 662, 692 may be as described in commonly owned U.S. Pat. Nos. 7,642,642; 8,232,845; 8,280,080; 9,793,874; and 9,793,877. The disclosures of these patents are specifically incorporated herein by reference. Illustratively, the first-third perimeter walls 642, 662, 692 each have a height “h” (z-direction in the coordinate system shown) of approximately 10.0 μm to approximately 70.0 μm, and a width “w” (x-direction in the coordinate system shown) of approximately 10.0 μmm to 200.0 μm. As described more fully below, bonding of the first substrate 602, the second substrate 622, and the third substrate 652, respective substantially hermetic seals are provided and protects the various components in the first cavity 648, the second cavity 668 and the third cavity 698 from ambient contaminants and debris.

Electrical conductors 570 are provided in the first-third perimeter walls 542, 562, 593, and selectively over other components of the electronic package 500 (e.g., the electrical conductors can be disposed over inner surfaces 644, 646, 664, 666, 694,696) to provide electrical connections as needed for operation of the filters of the electronic package 600. An illustrative example of electrical connections between BAW resonators on two different substrates (e.g., first and second BAW resonators 626, 686) is shown and described in connection with FIG. 4B, above.

Fabrication of the electronic package 600 is effected in substantively identical ways to those described above in connection with FIGS. 1A-3D and 5. Notably, the first, second and third BAW resonators 606, 626 and 686 are fabricated over respective first, second and third acoustic reflectors 604, 624, 684 disposed in the first, second and third substrates 602, 622, 652, respectively. Selective removal of portions of the first, second, third and fourth substrates 602, 622, 652, 682 is done by etching and grinding methods described above to reveal first, second and third cavities 648, 668 and 698, and to provide the proper thickness (z-direction in the coordinate system of FIG. 6) of selected substrates. Next, the first, second and third BAW resonators 606, 626 and 686 are tuned. After tuning, the first and second substrates 602, 622 may be bonded along the first perimeter wall 642 by a metal/allow-metal/alloy bonding technique noted above, or by a polymer-polymer technique described above. Similarly, the third substrate 652 and the fourth substrate 682 may be bonded along the third perimeter wall 692 by a metal/allow-metal/alloy bonding technique noted above, or by a polymer-polymer technique described above. Finally, these structures are bonded together along the interface of the inner surface 664 and the second perimeter wall 662 by a metal/allow-metal/alloy bonding technique noted above, or by a polymer-polymer technique described above.

In accordance with illustrative embodiments, bulk acoustic wave (BAW) resonators for various applications such as in electrical filters are described having an electrode comprising a cantilevered portion. Additionally, bulk acoustic wave (BAW) resonators for various applications such as in electrical filters are described. One of ordinary skill in the art appreciates that many variations that are in accordance with the present teachings are possible and remain within the scope of the appended claims. These and other variations would become clear to one of ordinary skill in the art after inspection of the specification, drawings and claims herein. The invention therefore is not to be restricted except within the spirit and scope of the appended claims.

We claim:

1. An electronic package, comprising:
a first substrate;
a second substrate disposed beneath the first substrate; and
a perimeter wall extending between an inner surface of the first substrate and an opposing inner surface of the second substrate to provide separation between the first substrate and the second substrate, wherein a cavity exists between opposing inner surfaces of the first substrate and the second substrate;
a first filter comprising a first plurality of bulk acoustic wave (BAW) resonators disposed over the inner surface of the first substrate; and
a second filter comprising a second plurality of BAW resonators disposed over the second substrate.

2. The electronic package as claimed in claim 1, wherein the perimeter wall is a first perimeter wall, the cavity is a first cavity, and the electronic package further comprises:
a third substrate disposed over the second substrate; and
a second perimeter wall extending between a surface of the first substrate and an opposing inner surface of the second substrate to provide separation between the first substrate and the second substrate, wherein a second cavity exists between opposing inner surfaces of the first substrate and the third substrate.

3. The electronic package as claimed in claim 2, wherein the second filter is disposed over an outer surface of the second substrate.

4. The electronic package as claimed in claim 1, wherein the perimeter wall is a first perimeter wall, the cavity is a first cavity, and the electronic package further comprises:
a third substrate disposed between the first and second substrates; and
a second perimeter wall extending between a surface of the first substrate and an opposing inner surface of the third substrate to provide separation between the first substrate and the second substrate, wherein a second cavity exists between opposing inner surfaces of the first substrate and the third substrate.

5. The electronic package as claimed in claim 4, wherein the second filter is disposed over the inner surface of the second substrate.

6. The electronic package as claimed in claim 3, wherein the first, second and third substrates, and the first and second perimeter walls each comprise a semiconductor material.

7. The electronic package as claimed in claim 6, further comprising electrical connections between the first, second and third substrates.

8. The electronic package as claimed in claim 5, wherein the first, second and third substrates, and the first and second perimeter walls each comprise a semiconductor material.

9. The electronic package as claimed in claim 8, further comprising electrical connections between the first, second and third substrates.

10. The electronic package as claimed in claim 2, further comprising a contact pad disposed over an outer surface of the third substrate.

11. The electronic package as claimed in claim 4, further comprising a contact pad disposed over an outer surface of the second substrate.

12. An electronic package, comprising:
a first substrate;
a second substrate disposed beneath the first substrate; and
a perimeter wall extending between a surface of the first substrate and an opposing inner surface of the second substrate to provide separation between the first substrate and the second substrate, wherein a cavity exists between opposing inner surfaces of the first substrate and the second substrate;
a first bulk acoustic wave (BAW) resonator disposed over the inner surface first substrate; and
a second BAW resonator disposed over the second substrate.

13. The electronic package as claimed in claim 12, wherein the perimeter wall is a first perimeter wall, the cavity is a first cavity, and the electronic package further comprises:
a third substrate disposed over the second substrate; and
a second perimeter wall extending between a surface of the first substrate and an opposing inner surface of the second substrate to provide separation between the first substrate and the second substrate, wherein a second cavity exists between opposing inner surfaces of the first substrate and the third substrate.

14. The electronic package as claimed in claim 13, wherein the second BAW resonator is disposed over an outer surface of the second substrate.

15. The electronic package as claimed in claim 13, wherein the perimeter wall is a first perimeter wall, the cavity is a first cavity, and the electronic package further comprises:
a third substrate disposed between the first and second substrates; and
a second perimeter wall extending between a surface of the first substrate and an opposing inner surface of the third substrate to provide separation between the first substrate and the second substrate, wherein a second cavity exists between opposing inner surfaces of the first substrate and the third substrate.

16. The electronic package as claimed in claim 15, wherein the second BAW resonator is disposed over the inner surface of the second substrate.

17. The electronic package as claimed in claim 13, wherein the first, second and third substrates, and the first and second perimeter walls each comprise a semiconductor material.

18. The electronic package as claimed in claim 17, further comprising electrical connections between the first, second and third substrates.

19. The electronic package as claimed in claim 18, further comprising electrical connections between the first, second and third substrates.

20. The electronic package as claimed in claim 15, wherein the first, second and third substrates, and the first and second perimeter walls each comprise a semiconductor material.

21. The electronic package as claimed in claim 20, further comprising electrical connections between the first, second and third substrates.

22. The electronic package as claimed in claim 13, further comprising a contact pad disposed over an outer surface of the third substrate.

23. The electronic package as claimed in claim 14, further comprising a contact pad disposed over an outer surface of the second substrate.

24. An electronic package, comprising:
a first substrate;
a second substrate disposed beneath the first substrate; and
a polymer perimeter wall extending between a surface of the first substrate and an opposing inner surface of the second substrate to provide separation between the first substrate and the second substrate, wherein a cavity exists between opposing inner surfaces of the first substrate and the second substrate;
a first filter comprising a first plurality of bulk acoustic wave (BAW) resonators disposed over the inner surface first substrate; and
a second filter comprising a second plurality of BAW resonators disposed over the inner surface of the second substrate.

25. The electronic package as claimed in claim 24, further comprising electrical connections between the first and second substrates.

26. The electronic package as claimed in claim 25, wherein electrical connections are disposed over at least some of the polymer perimeter wall.

27. The electronic package as claimed in claim 24, wherein at least some of the polymer perimeter wall comprises a first polymer perimeter wall connected to the first substrate, and a second polymer perimeter wall connected to the second substrate, and a bonding material disposed the first and second perimeter walls.
